(19) United States
(12) Patent Application Publication
(10) Pub. No.: US 2012/0126397 A1
(43) Pub. Date: May 24, 2012

(54) SEMICONDUCTOR SUBSTRATE AND METHOD THEREOF

(75) Inventors: Feng-Lung Chien, Taichung (TW); Yi-Hsin Chen, Taichung (TW); Kuei-Hsiao Kuo, Taichung (TW)

(73) Assignee: SILICONWARE PRECISION INDUSTRIES CO., LTD., Taichung (TW)

(21) Appl. No.: 12/987,571

(22) Filed: Jan. 10, 2011

(30) Foreign Application Priority Data
Nov. 23, 2010 (TW) 099140299

(51) Int. Cl. H01L 23/498; B05D 5/12; B23K 1/20

(52) U.S. Cl. 257/737; 228/176; 257/E23.068

(57) ABSTRACT

A semiconductor substrate includes a substrate having plurality of electrical contact pads formed thereon, a first insulating protective layer formed on the substrate that exposes the electrical contact pads, a plurality of metal layers formed on the exposed electrical contact pads, a second insulating protective layer formed on the first insulating protective layer that exposes a portion of the metal layers, and a plurality of solder bumps formed on the exposed metal layers having copper. Through the second insulating protective layer covering a portion of the metal layers, the solder bumps are prevented from falling off or crack when the semiconductor substrate is under a temperature test.

### BACKGROUND OF THE INVENTION

1. Field of the Invention

This invention relates to semiconductor substrates and methods thereof, and, more particularly, to a semiconductor substrate having solder bumps and a method for fabricating the same.

2. Description of Related Art

With the rapid development of electronic technology, an electronic produce is designed to have a variety of high-end functions. A semiconductor chip is wire bonded to a package substrate or installed on the package substrate in a flip-chip manner. Golden wires or conductive bumps are installed between the chip and the package substrate to electrically connect the chip to the package substrate.

U.S. Pat. No. 6,107,180 and U.S. Pat. No. 6,111,321 disclose a semiconductor device. Referring to FIG. 1, a cross section view of a semiconductor device 1 according to the prior art is shown.

The semiconductor device 1 is composed of a wafer 10 having electrical contact pads 100, an insulating protective layer 11 formed on the wafer 10 that exposes the electrical contact pads 100, an under bump metal (UBM) layer 12 formed on the exposed electrical contact pads 100, and solder bumps 16 formed on the UBM layer 12.

However, theres is a coefficient of thermal expansion (CTE) mismatch between the wafer 10 and the UBM layer 12. Accordingly, the UBM layer 12 is likely peeled off, and the solder bumps 16 may fall off or crack, when the semiconductor device 1 is under a temperature test. Therefore, the electrical contact pads 100 may not be electrically connected to the package substrate effectively during a subsequent flip-chip process, which results in a low yield of a semiconductor product.

Referring to FIGS. 2A and 2B, cross sectional views of another semiconductor device 1′ according to the prior art are shown. As shown in FIG. 2A, a resistive layer 15 is formed on a wafer 10′ having electrical contact pads 100′, and the resistive layer 15 is exposed and developed to form a plurality of openings 150 that expose the electrical contact pads 100′. Then, solder paste 160 is applied on the electrical contact pads 100′ exposed from the openings 150. As shown in FIG. 2B, the resistive layer 15 is removed, and the solder paste 160 is reflowed to form solder bumps 16′.

However, the openings 150 are not completely filled with the solder paste 160 since the solder paste 160 is aoolied on the electrical contact pads 100′ exposed from the openings 150. As a result, the solder bumps 16′ are likely to form voids, and are likely to be melted locally due to electro migration (EM). Therefore, the electrical contact pads 100′ may not be electrically connected to the package substrate effectively during the subsequent flip-chip process, and the semiconductor product may thus have a low yield.

Therefore, how to solve the above-mentioned problems of the prior art is becoming a crucial issue in the art.

### SUMMARY OF THE INVENTION

In view of the above-mentioned problems of the prior art, the present invention provides a semiconductor substrate that includes: a substrate having a plurality of electrical contact pads formed thereon; a first insulating protective layer formed on the substrate and the electrical contact pads, the first insulating protective layer having a plurality of first openings for exposing the electrical contact pads; a plurality of metal layers formed on the electrical contact pads and extending onto a portion of the first insulating protective layer; a second insulating protective layer formed on the first insulating protective layer and the metal layers, the second insulating protective layer having a plurality of second openings for exposing the metal layers, such that the second insulating protective layer covers a portion of each of the metal layers extending onto the portion of the first insulating protective layer; and a plurality of solder bumps formed on the metal layers exposed from the second openings.

In an embodiment of the present invention, the metal layers are under bump metal layers, and the under bump metal layer is made of titanium/copper/nickel, or titanium/nickel/vanadium/copper.

In an embodiment of the present invention, the solder bumps are made of tin.

In an embodiment of the present invention, the solder bumps have copper.

The present invention further provides a method for fabricating a semiconductor substrate. The method includes: providing a substrate having a plurality of electrical contact pads formed thereon and a first insulating protective layer covering the electrical contact pads, the first insulating protective layer having a plurality of first openings for exposing the electrical contact pads; forming a plurality of metal layers in the first openings and on the electrical contact pads, the metal layers extending onto a portion of the first insulating protective layer; forming on the first insulating protective layer and the metal layers a second insulating protective layer with a plurality of second openings for exposing the metal layers, the second insulating protective layer covering a portion of each of the metal layers extending onto the portion of the first insulating protective layer; and forming a plurality of solder bumps formed on the metal layers exposed from the second openings.

In an embodiment of the present invention, the solder bumps are formed by: forming a copper layer on the second insulating protective layer and on the metal layers exposed from the second openings; forming on the copper layer a resistive layer with a plurality of third openings for exposing the copper layer on the metal layers; applying solder paste in the third openings and on the copper layer exposed from the third openings; removing the resistive layer and the copper layer under the resistive layer; and reflowing the solder paste and the copper layer under the solder paste, so as to form the solder bumps having copper.

In an embodiment of the present invention, the solder paste is electroplated in the third openings and on the copper layer exposed from the third openings.

In an embodiment of the present invention, the substrate is a wafer.

In the semiconductor substrate and the method for fabricating the same according to the present invention, the second insulating protective layer covers a portion of each of the metal layers. Therefore, the solder bumps are prevented from falling off or crack when the semiconductor substrate is under a temperature test.

Since the solder paste is electroplated in the third openings and on the copper layer in the third openings, the third openings are completely filled with the solder paste. Accordingly, the solder bumps are formed without voids, and a poor electric connection of the solder bumps caused by a local melting is avoided.

### BRIEF DESCRIPTION OF DRAWINGS

The invention can be more fully understood by reading the following detailed description of the preferred embodiments, with reference made to the accompanying drawings, wherein:

FIG. 1 is a partial cross sectional view of a semiconductor device according to the prior art;

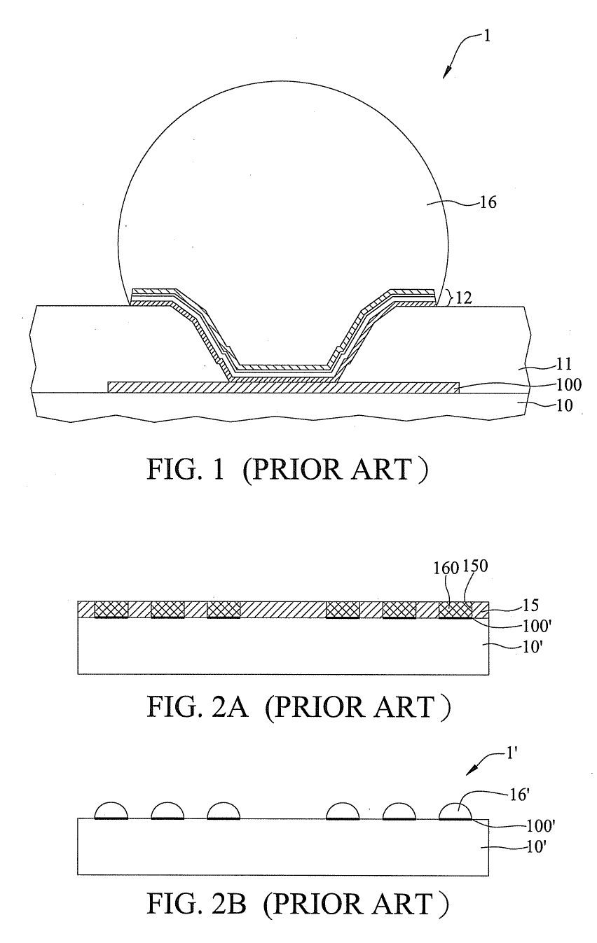

FIGS. 2A and 2B are cross sectional views of another semiconductor devices according to the prior art;

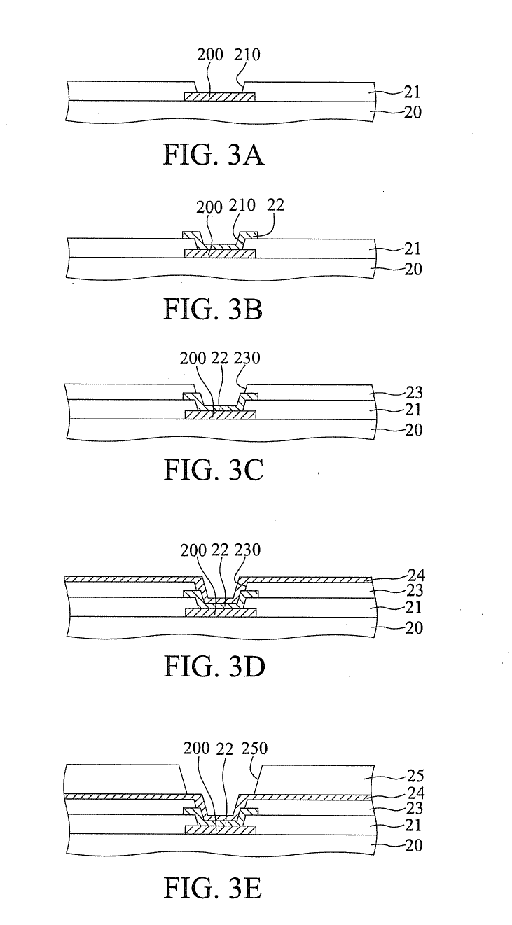

FIGS. 3A-3H are cross sectional views of a semiconductor substrate of an embodiment according to the present invention.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

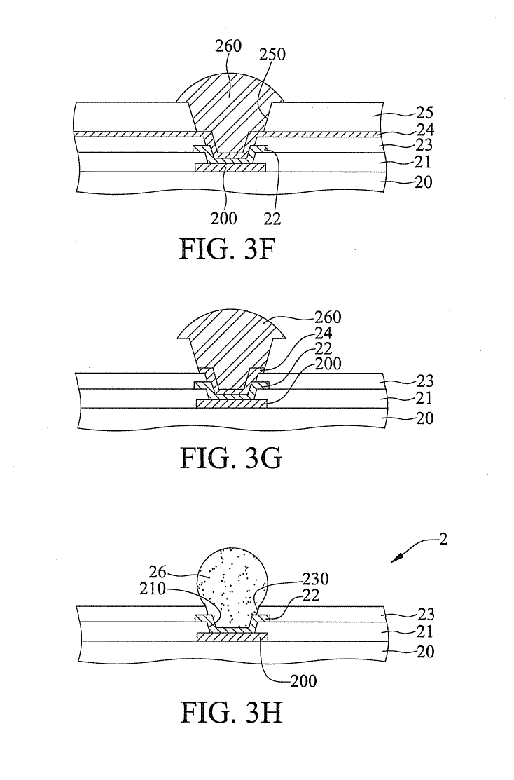

Referring to FIGS. 3A-3H, cross sectional views of a semiconductor substrate 2 of an embodiment according to the present invention are illustrated.

As shown in FIG. 3A, a substrate 20 has electrical contact pads 200 formed thereon and a first insulating protective layer 21 that covers the electrical contact pads 200. The first insulating protective layer 21 has a plurality of first openings 210 that expose the electrical contact pads 200. In an embodiment, the substrate 20 may be a flip-chip wafer.

As shown in FIG. 3B, a plurality of metal layers 22 are formed on a wall in each of the first openings 210 and on the electrical contact pads 200. The metal layers 22 also extend to a portion of each of the first insulating protective layer 21.

In an embodiment, the metal layers 22 are an under bump metal layer, and the under bump metal layer is made of titanium/copper/nickel, or titanium/nickel/vanadium/copper. In an embodiment, the metal layers 22 may be formed by a sputtering or plating process in cooperation with exposure and development processes in a patterning process.

As shown in FIG. 3C, a second insulating protective layer 23 is formed on the first insulating protective layer 21 and the metal layers 22. The second insulating protective layer 23 has a plurality of second openings 230 that expose the metal layers 22. The second insulating protective layer 23 covers the metal layers 22 on the first insulating protective layer 21.

As shown in FIG. 3D, a copper layer 24 is formed on the second insulating protective layer 23 and on the metal layers 22 exposed from the second openings 230 by the sputtering process.

As shown in FIG. 3E, a resistive layer 25 is formed on the copper layer 24. In an embodiment, the resistive layer 25 may be a photoresist, and a plurality of patterned third openings 250 may be formed by exposing and developing the photoresist. The third openings 250 expose the copper layer 24 on the metal layers 22. As shown in FIGS. 3A-3E, the second openings 230 are formed corresponding in position to the first openings 210, and the third openings 250 are formed corresponding in position to the second openings 230.

As shown in FIG. 3F, solder paste 260 is electroplated in the third openings 250, in the second openings 230, and on the copper layer 24. In an embodiment, the solder paste 260 is made of tin.

As shown in FIG. 3G, the resistive layer 25 is removed, and the copper layer 24 under the resistive layer 25 is etched and removed, keeping the copper layer 24 under the solder paste 260 intact.

As shown in FIG. 3H, the solder paste 260 is reflowed to form solder bumps 26. At the same time, the copper layer 24 under the solder paste 260 may be reflowed with the solder bumps 26, so as to form on the metal layers 22 exposed from in the second openings 230 the solder bumps 26 that have copper. In an embodiment, the solder bumps 26 are electrically connected in a flip chip manner to a package substrate.

In the present invention, the second insulating protective layer 23 covers the metal layers 22, so as to prevent the peeling of the metal layers 22 from occurence. Therefore, when the semiconductor substrate 2 is under a temperature test, the solder bumps 26 are prevented from falling off or crack. Accordingly, the electrical contact pads 200 are allowed to be electrically connected to the package substrate effectively during a subsequent flip chip process, and the fabrication of the semiconductor product thus has an improved yield.

Since the solder paste 260 is electroplated in the third openings 250 and the second openings 230, the third openings 250 and the second openings 230 are completely filled with the solder paste 260. Besides, the solder paste 260 is reflowed to form the solder bumps 26 and the copper layer 24 is reflowed with the solder bumps 26. Therefore, the solder bumps 26 are formed without voids, and a poor electric connection of the solder bumps caused by a local melting is avoided. Accordingly, the electrical contact pads 200 are electrically connected to the package substrate effectively during a subsequent flip chip process, and the fabrication of the semiconductor product thus has an improved yield.

The present invention further provides the semiconductor substrate 2 that has: the substrate 20 with the electrical contact pads 200 formed thereon, the first insulating protective layer 21 formed on the substrate 20 for exposing the electrical contact pads 200, the metal layers 22 formed on the electrical contact pads 200, the second insulating protective layer 23 formed on the first insulating protective layer 21 and the metal layers 22, and the solder bumps 26 formed on the metal layers 22 that have copper.

In an embodiment, the substrate 20 is a wafer.

The first insulating protective layer 21 has the first openings 210 that expose the electrical contact pads 200.

The metal layers 22 are formed on the electrical contact pads 200 exposed from the first openings 210, and extend to a portion of the first insulating protective layer 21. In an embodiment, the metal layers 22 are an under bump metal layer, and the under bump metal layer is made of titanium/copper/nickel, or titanium/nickel/vanadium/copper.

The second insulating protective layer 23 is formed with the second openings 230 that expose the metal layers 22. The second insulating protective layer 23 covers the metal layers 22 that extend onto the first insulating protective layer 21.

The solder bumps 26 that have copper are formed on the metal layers 22 exposed from the second openings 230. In an embodiment, the solder bumps 26 are made of tin.

In the semiconductor substrate and the method thereof of the present invention, the second insulating protective layer covers the metal layers. Therefore, the solder bumps do not fall off or crack when the semiconductor substrate is under a temperature test.

The solder paste is electroplated in the third openings and the second openings, such that the third openings and the second openings are allowed to be completely filled with the solder paste. Besides, the solder paste is reflowed to form the solder bumps and the copper layer is reflowed with the solder bumps. Therefore, the solder bumps are formed without voids, and a poor electric connection of the solder bumps caused by a local melting is avoided.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A semiconductor substrate, comprising:
a substrate having a plurality of electrical contact pads formed thereon;
a first insulating protective layer formed on the substrate and the electrical contact pads, and formed with a plurality of first openings for exposing the electrical contact pads;
a plurality of metal layers formed on the electrical contact pads exposed from the first openings and extending onto a portion of the first insulating protective layer;
a second insulating protective layer formed on the first insulating protective layer and the metal layers, the second insulating protective layer being formed with a plurality of second openings for exposing the metal layers in a manner that a portion of each of the metal layers extending onto the portion of the first insulating protective layer is covered by the second insulating protective layer; and
a plurality of solder bumps formed on the metal layers in the second openings.

2. The semiconductor substrate of claim 1, wherein the substrate is a wafer.

3. The semiconductor substrate of claim 1, wherein the metal layers are under bump metal layers.

4. The semiconductor substrate of claim 3, wherein the under bump metal layer is made of titanium/copper/nickel, or titanium/nickel/vanadium/copper.

5. The semiconductor substrate of claim 1, wherein the solder bumps are made of tin.

6. The semiconductor substrate of claim 1, wherein the solder bumps comprise copper.

7. A method of fabricating a semiconductor substrate, comprising:
providing a substrate having a plurality of electrical contact pads formed thereon and a first insulating protective layer covering the electrical contact pads, the first insulating protective layer being formed with a plurality of first openings for exposing the electrical contact pads;
forming a plurality of metal layers in the first openings and on the electrical contact pads exposed from the first openings, the metal layers extending onto a portion of the first insulating protective layer;
forming on the first insulating protective layer and the metal layers a second insulating protective layer with a plurality of second openings for exposing the metal layers, the second insulating protective layer covering a portion of each of the metal layers extending onto the portion of the first insulating protective layer; and
forming a plurality of solder bumps on the metal layers exposed from the second openings.

8. The method of claim 7, wherein the substrate is a wafer.

9. The method of claim 7, wherein the solder bumps are formed by the steps of:
forming a copper layer on the second insulating protective layer and on the metal layers exposed from the second openings;
forming on the copper layer a resistive layer with a plurality of third openings for exposing the copper layer on the metal layers;
applying solder paste in the third openings and on the copper layer exposed from the third openings;
removing the resistive layer and the copper layer under the resistive layer; and
reflowing the solder paste and the copper layer under the solder paste to form the solder bumps having copper.

10. The method of claim 9, wherein the solder paste is electroplated in the third openings and on the copper layer exposed from the third openings.
